(19) United States
(12) Patent Application Publication
(10) Pub. No.: US 2021/0408415 A1
(43) Pub. Date: Dec. 30, 2021

(54) DISPLAY PANEL AND MANUFACTURING METHOD OF DISPLAY PANEL

(71) Applicant: Shenzhen China Star Optoelectronics Semiconductor Display Technology Co., LTD., Shenzhen (CN)

(72) Inventor: Ming LIU, Shenzhen (CN)

(73) Assignee: Shenzhen China Star Optoelectronics Semiconductor Display Technology Co., LTD., Shenzhen (CN)

(21) Appl. No.: 16/624,325

(22) PCT Filed: Nov. 28, 2019
(86) PCT No.: PCT/CN2019/121582

§ 371 Date: Dec. 19, 2019

(30) Foreign Application Priority Data
Nov. 21, 2019 (CN) 201911146664.8

(51) Int. Cl. H01L 51/50; H01L 51/52; H01L 51/00; H01L 51/56

(52) U.S. Cl. CPC H01L 51/502; H01L 51/5271; H01L 51/56; H01L 51/5237; H01L 51/001; H01L 51/5275

(57) ABSTRACT

The present invention discloses a display panel and a manufacturing method of the display panel. The display panel includes: a substrate, a light-emitting device layer, and a cover plate stacked sequentially; a quantum dot light conversion film disposed on a side of the substrate away from the light-emitting device layer; and an optical adjustment film disposed between the substrate and the quantum dot light conversion film.

### CROSS-REFERENCE TO RELATED APPLICATIONS

This application claims the priority to Chinese Patent Application No. 201911146664.8, entitled “DISPLAY PANEL AND MANUFACTURING METHOD OF DISPLAY PANEL” and filed on Nov. 21, 2019 with the State Intellectual Property Office of the People's Republic of China, which is entirely incorporated by reference into the present application.

### FIELD OF INVENTION

The present invention is related to the field of display technology, and specifically to a display panel and a manufacturing method of the display panel.

### BACKGROUND OF INVENTION

Quantum dot organic light-emitting diodes (QD-OLEDs), a new generation display technology, use blue organic light-emitting diodes (B-OLEDs) as a light source. A quantum dot film is disposed on an exit port of light, and blue light of the B-OLEDs excites the quantum dot film to emit light.

The QD-OLEDs have advantages of wide color gamut of quantum dots and bright and distinct colors. They also have advantages of low costs, flexibility, and bendability as OLEDs. Therefore, the QD-OLEDs have huge potential and a broad, promising development. Theoretically, the QD-OLEDs emit light by the blue light from the B-OLEDs and photo-emissive quantum dots. Photoluminescence of quantum dots is isotropic. After being excited, photons are emitted and scattered in all directions, and a part of the photons are emitted into the OLED. They are either absorbed or trapped, causing a waste of energy.

### SUMMARY OF INVENTION

Currently, the QD-OLED has a technical problem of low light utilization due to the scattered photons emitted in all directions after being excited.

The present invention provides a display panel and a manufacturing method of the display panel, which solves the technical problem of the OLED in the prior art having low light utilization due to the scattered photons emitted in all directions after being excited.

In order to solve the problem above, in a first aspect, the present invention provides a display panel including:

a substrate, a light-emitting device layer, and a cover plate stacked sequentially;

a quantum dot light conversion film disposed on a side of the substrate away from the light-emitting device layer; and

an optical adjustment film disposed between the substrate and the quantum dot light conversion film.

In some embodiments, the optical adjustment film is formed by alternately stacking a plurality of refractive units, and each of the plurality of refractive units includes a first material layer having a refractive index n1 and a second material layer having a refractive index n2.

In some embodiments, the refractive index n1 of the first material layer is less than 1.6, and the refractive index n2 of the second material layer is greater than 2.0.

In some embodiments, a material of the first material layer is selected from the group consisting of magnesium fluoride, calcium fluoride, and silicon oxide, and a material of the second material layer is selected from the group consisting of zinc tin oxide, zinc sulfide, and zirconium oxide.

In some embodiments, the quantum dot light conversion film is doped with quantum dots capable of emitting red, green, or yellow light.

In some embodiments, the light-emitting device layer is a blue light-emitting device layer.

In some embodiments, when a wavelength of incident light ranges from 490 to 670 nm, and a reflectance of the optical adjustment film is higher than 90%.

In some embodiments, when a wavelength of incident light is less than 490 nm, a reflectance of the optical adjustment film is lower than 10%.

In some embodiments, the light-emitting device layer includes a transparent electrode, an organic layer, and a reflective electrode.

In a second aspect, the present invention further provides a manufacturing method of a display panel, including:

sequentially forming a light-emitting device layer and a cover plate on a side of a substrate;

forming an optical adjustment film on another side of the substrate; and

forming a quantum dot light conversion film on a surface of the optical adjustment film to obtain the display panel;

wherein a method for forming the optical adjustment film is one of vacuum evaporation, magnetron sputtering, chemical deposition, or atomic layer deposition.

In some embodiments, a method for forming the light-emitting device layer is vacuum evaporation, and a method for forming the quantum dot light conversion film is coating or bonding after separate preparation.

In some embodiments, the display panel includes:

the substrate, the light-emitting device layer, and the cover plate stacked sequentially;

the quantum dot light conversion film disposed on a side of the substrate away from the light-emitting device layer; and

the optical adjustment film disposed between the substrate and the quantum dot light conversion film.

In some embodiments, the optical adjustment film is formed by alternately stacking a plurality of refractive units, and each of the plurality of refractive units includes a first material layer having a refractive index n1 and a second material layer having a refractive index n2.

In some embodiments, the refractive index n1 of the first material layer is less than 1.6, and the refractive index n2 of the second material layer is greater than 2.0.

In some embodiments, a material of the first material layer is selected from the group consisting of magnesium fluoride, calcium fluoride, and silicon oxide, and a material of the second material layer is selected from the group consisting of zinc tin oxide, zinc sulfide, and zirconium oxide.

In some embodiments, the quantum dot light conversion film is doped with quantum dots capable of emitting red, green, or yellow light.

In some embodiments, the light-emitting device layer is a blue light-emitting device layer.

In some embodiments, a wavelength of incident light ranges from 490 to 670 nm, and a reflectance of the optical adjustment film is higher than 90%.

In some embodiments, a wavelength of incident light is less than 490 nm, a reflectance of the optical adjustment film is lower than 10%.

In some embodiments, the light-emitting device layer includes a transparent electrode, an organic layer, and a reflective electrode.

Compared to the prior art, the present invention adds an optical adjustment film between the substrate and the quantum dot light conversion film. The optical adjustment film has a specific structure having a special light reflection and transmittance. It can selectively transmit blue light emitted from the light-emitting device layer, and reflect red light, green light, or yellow light emitted by the quantum dots in a direction of light emission, which improves the light utilization.

### DESCRIPTION OF DRAWINGS

The following describes specific embodiments of the present invention in detail with reference to the accompanying drawings, which will make technical solutions and other beneficial effects of the present invention obvious.

FIG. 1 is a structural diagram of a display panel of an embodiment of the present invention.

FIG. 2 is a reflectance spectrum of an optical adjustment film of an embodiment of the present invention.

FIG. 3 is a flowchart of a manufacturing method of the display panel of an embodiment of the present invention.

### REFERENCE SIGNS

substrate 10, light-emitting device layer 20, transparent electrode 201, organic layer 202, reflective electrode 203, cover plate 30, quantum dot light conversion film 40, and optical adjustment film 50.

### DETAILED DESCRIPTION OF PREFERRED EMBODIMENTS

To further explain the technical means and effect of the present invention, the following refers to embodiments and drawings for detailed description. Obviously, the described embodiments are only for some embodiments of the present invention, instead of all embodiments. Based on the embodiments of the present invention, all other embodiments obtained by those skilled in the art without creative work fall into a protection scope of the present invention.

Directional terms mentioned in the present invention, such as upper, lower, front, rear, left, right, in, out, side, etc., only refer to directions in the accompanying drawings. Thus, the adoption of directional terms is used to describe and understand the present invention, but not to limit the present invention. In addition, the terms “first” and “second” are merely used for illustrative purposes only, but are not to be construed as indicating or imposing a relative importance or implicitly indicating the number of technical features indicated. Thus, a feature that defines “first” or “second” may expressly or implicitly include one or more of the features. In the description of the present invention, the meaning of “plural” is two or more, unless otherwise specified.

In the present invention, unless otherwise specifically stated and defined, terms “connected”, “fixed”, etc. should be interpreted expansively. For example, “fixed” may be fixed connection, also may be detachable connection, or integration; may be mechanical connection, also may be electrical connection; may be direct connection, also may be indirect connection through an intermediate, and may be internal communication between two elements or interaction of two elements, unless otherwise specifically defined. The ordinary skill in this field can understand the specific implication of the above terms in the present disclosure according to specific conditions.

In the present invention, unless otherwise specifically stated and defined, a structure in which a first feature is “on” or “below” a second feature may include an embodiment in which the first feature is in direct contact with the second feature, and may also include an embodiment in which the first feature and the second feature are not in direct contact with each other, but are contacted via an additional feature formed therebetween. Furthermore, a first feature “on,” “above,” or “on top of” a second feature may include an embodiment in which the first feature is right or obliquely “on,” “above,” or “on top of” the second feature, or just means that the first feature is at a height higher than that of the second feature; while a first feature “below,” “under,” or “on bottom of” a second feature may include an embodiment in which the first feature is right or obliquely “below,” “under,” or “on bottom of” the second feature, or just means that the first feature is at a height lower than that of the second feature.

Various embodiments or examples are provided here below to implement the different structures of the present invention. To simplify the disclosure of the present invention, description of the components and arrangements of specific examples is given below. Of course, they are only illustrative and not limiting the present invention. Moreover, in the present invention, reference numbers and/or letters may be repeated in different embodiments. Such repetition is for the purposes of simplification and clearness, and does not denote the relationship between respective embodiments and/or arrangements being discussed. Furthermore, the present invention provides various examples for specific process and materials. However, it is obvious for a person of ordinary skill in the art that other processes and/or materials may alternatively be utilized.

Currently, the QD-OLED has a technical problem of low light utilization due to the scattered photons emitted in all directions after being excited.

Based on this, embodiments of the present invention provide a display panel and a manufacturing method of the display panel. Each of them will be described in detail below.

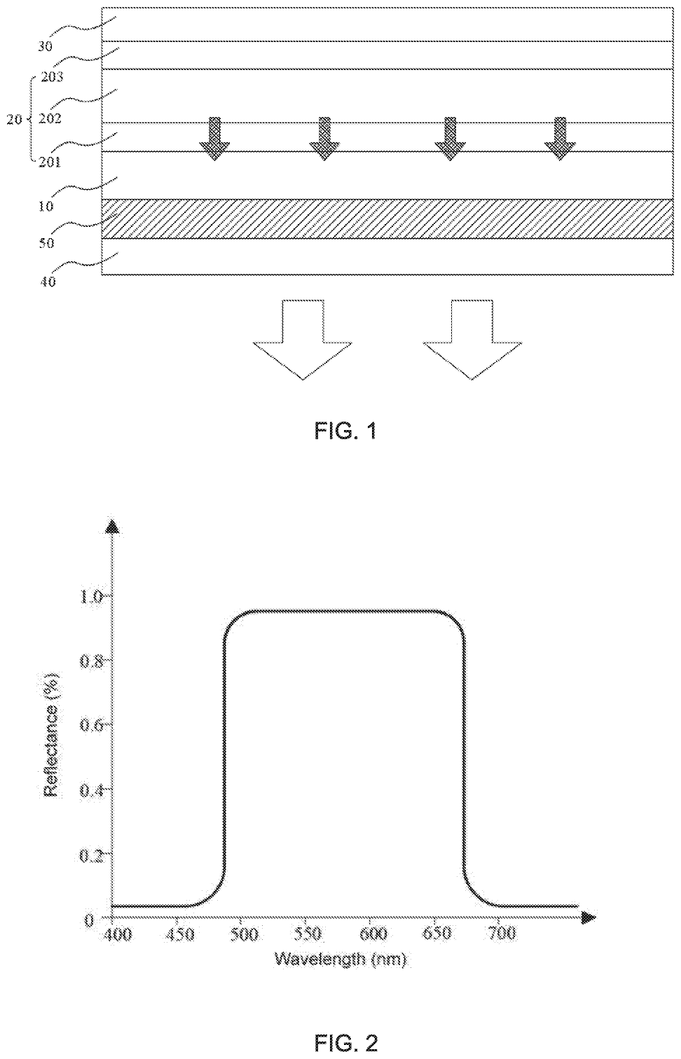

First, the present invention provides a display panel as shown in FIG. 1, which is a structural diagram of a display panel of an embodiment of the present invention. The display panel includes a substrate 10, a light-emitting device layer 20, and a cover plate 30 stacked sequentially; a quantum dot light conversion film 40 disposed on a side of the substrate 10 away from the light-emitting device layer 20; and an optical adjustment film 50 disposed between the substrate 10 and the quantum dot light conversion film 40.

In this embodiment, the substrate 10 is a transparent substrate, and is preferably a glass or a polyethylene terephthalate (PET) plastic film. The light-emitting device layer 20 includes a transparent electrode 201, an organic layer 202, and a reflective electrode 203. The transparent electrode 201 is disposed on a surface of the substrate 10, the organic layer 202 is disposed on a surface of the transparent electrode 201, and the reflective electrode 203 is disposed on a surface of the organic layer 202. Specifically, the transparent electrode 201 is preferably indium tin oxide (ITO). The organic layer 202 is a collective name of various film layers made of an organic material. The organic layer 202 includes at least one layer of a hole blocking layer, a hole transport layer, a hole injection layer, a light-emitting layer, an electron blocking layer, an electron transport layer, and an electron injection layer. When the organic layer 202 includes a plurality of organic film layers, each of the plurality of organic film layers may exist in a form of a conventional single section or a series structure. The reflective electrode 203 is made of a metal material, which is preferably a metal material with excellent electrical conductivity, and aluminum, silver, or magnesium silver is the most preferred alloy.

Generally, because energy of blue light is high, the light-emitting device layer 20 is preferably a blue light-emitting device layer, and a light-emitting layer in the organic layer 202 emits blue light. A part of the blue light emitted by the light-emitting layer passes through the transparent electrode 201 and is emitted in a direction of light emission, and another part of the blue light is emitted in an opposite direction, reflected by the reflective electrode 203, and then emitted in the direction of light emission, which improves the light utilization. The quantum dot light conversion film 40 is disposed on a side of the substrate 10 away from the light-emitting device layer 20. The quantum dot light conversion film 40 is doped with quantum dots capable of emitting red, green, or yellow light. The quantum dots can be excited by the blue light, thereby emitting red light, green light, or yellow light, and the red light, the green light, or the yellow light can be combined with the blue light to form white light.

On a basis of the above embodiment, in another embodiment of the present invention, the optical adjustment film 50 is disposed between the substrate 10 and the quantum dot light conversion film 40. The optical adjustment film 50 is formed by alternately stacking a plurality of refractive units, and each of the plurality of refractive units includes a first material layer having a refractive index n1 and a second material layer having a refractive index n2. In this way, the optical adjustment film 50 has a special light reflection and transmittance. As shown in FIG. 2, which is a reflectance spectrum of the optical adjustment film 50 of an embodiment of the present invention, the optical adjustment film 50 in this embodiment has the following characteristics: when a wavelength of incident light ranges from 490 to 670 nm, a reflectance of the optical adjustment film 50 is higher than 90%; and when a wavelength of incident light is less than 490 nm, a reflectance of the optical adjustment film is lower than 10%. Actually, wavelengths of various visible light colors are: a wavelength of the red light ranges from 622 to 770 nm, a wavelength of the yellow light ranges from 577 to 597 nm, a wavelength of the green light ranges from 592 to 577 nm, and a wavelength of the blue light ranges from 455 to 492 nm. Therefore, the optical adjustment film 50 has strong reflection ability for the red light, green light, and the yellow light, and has good transmittance for the blue light.

In this embodiment, analyses of the specific optical path are as follows: a part of the blue light emitted by the organic layer 202 is directly emitted in the direction of light emission, and another part of the blue light is emitted in an opposite direction, reflected by the reflective electrode 203, and then emitted in the direction of light emission. The two parts of the blue light can pass through the transparent electrode 201, which means that the light-emitting device layer 20 emits the blue light in the direction of light emission. After the blue light emitted by the light-emitting device layer 20 passes through the optical adjustment film 50, a part of the blue light directly reaches the outside, and another part of the blue light is used to excite the quantum dots in the quantum dot light conversion film 40. A part of the red light, the green light, and the yellow light emitted after excitation is directly emitted in the direction of light emission, and another part is emitted in a direction to the light-emitting device layer 20 but reflected by the optical adjustment film 50. The two parts of the ed light, the green light, and the yellow light can emit light in the direction of light emission. Meanwhile, the red light, the green light, or the yellow light emitted in the direction of light emission can be combined with the blue light directly arrived at outside to form white light. As shown in FIG. 1, shaded arrows indicate an emission direction of the blue light, and white arrows indicate an emission direction of the white light. This design improves the light utilization.

Of course, in this embodiment of the present invention, the optical adjustment film 50 can be further optimized. The plurality of refractive units include the first material layer having the refractive index n1 and a thickness dA and a second material layer having a refractive index n2 and a thickness dB. The optical adjustment film 50 is formed by alternately stacking the plurality of refractive units with different thicknesses. An nth refractive unit of the optical adjustment film 50 can reflect light of a specific wavelength, which satisfies the following relationship: when the wavelength is λ=2(n1×dAn+n2×dBn), the light is reflected by the nth refractive unit. In this embodiment, a wavelength to be reflected covers a range from 490 to 670 nm through setting the plurality of refractive units with different preset thicknesses. Therefore, the optical adjustment film 50 has strong reflection ability for the red light, the green light, and the yellow light, and has good transmittance for the blue light. Meanwhile, the refractive index n1 of the first material layer is preferably less than 1.6, and the refractive index n2 of the second material layer is preferably greater than 2.0. A material of the first material layer is preferably selected from the group consisting of magnesium fluoride, calcium fluoride, and silicon oxide, and a material of the second material layer is preferably selected from the group consisting of zinc tin oxide, zinc sulfide, and zirconium oxide. Because a required reflection wavelength range, the refractive index of the first material layer, and the refractive index of the second material layer are known, the different preset thicknesses of the plurality of refractive units can be calculated, which is not be repeated herein.

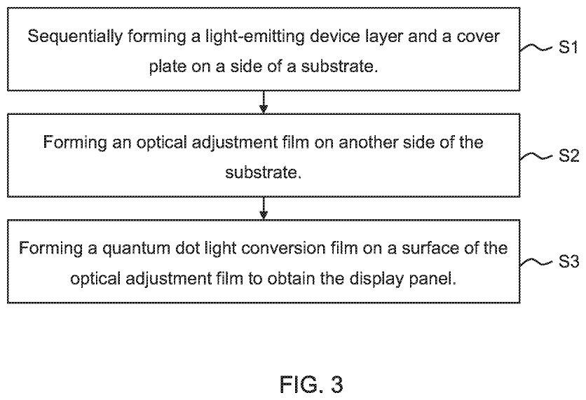

In order to better manufacture the display panel in an embodiment of the present invention, on a basis of the display panel above, this embodiment of the present invention also provides a manufacturing method of a display panel. As shown in FIG. 3, which is a flowchart of the manufacturing method of the display panel of this embodiment of the present invention, the manufacturing method includes:

S1, sequentially forming a light-emitting device layer and a cover plate on a side of a substrate;

S2, forming an optical adjustment film on another side of the substrate; and

S3, forming a quantum dot light conversion film on a surface of the optical adjustment film to obtain the display panel;

wherein a method for forming the optical adjustment film is one of vacuum evaporation, magnetron sputtering, chemical deposition, or atomic layer deposition.

Specifically, the light-emitting device layer includes a transparent electrode, an organic layer, and a reflective electrode. The step S1 further includes: forming the transparent electrode on the substrate; forming the organic layer on a surface of the transparent electrode by vacuum evaporation, forming the reflective electrode on a surface of the organic layer by vacuum evaporation. A method for forming the quantum dot light conversion film is coating or bonding after separate preparation. The vacuum evaporation, the coating, or the bonding after separate preparation are preferable methods, and in an actual production, other conventional methods can also be used to achieve this goal.

The present invention adds the optical adjustment film between the substrate and the quantum dot light conversion film. The optical adjustment film has a specific structure having a special light reflection and transmittance. It can selectively transmit blue light emitted from the light-emitting device layer, and reflect red light, green light, or yellow light emitted by the quantum dots in a direction of light emission, which improves the light utilization.

In the above embodiments, the description of each embodiment has its own emphasis. For a part that is not described in detail in one embodiment, reference may be made to related descriptions in other embodiments.

Although the present invention has been disclosed above by the preferred embodiments, the preferred embodiments are not intended to limit the invention. One of ordinary skill in the art, without departing from the spirit and scope of the present invention, can make various modifications and variations of the present invention. Therefore, the scope of the claims to define the scope of equivalents.

What is claimed is:

1. A display panel, comprising:
a substrate, a light-emitting device layer, and a cover plate stacked sequentially;
a quantum dot light conversion film disposed on a side of the substrate away from the light-emitting device layer; and
an optical adjustment film disposed between the substrate and the quantum dot light conversion film.

2. The display panel according to claim 1, wherein the optical adjustment film is formed by alternately stacking a plurality of refractive units, and each of the plurality of refractive units comprises a first material layer having a refractive index n1 and a second material layer having a refractive index n2.

3. The display panel according to claim 2, wherein the refractive index n1 of the first material layer is less than 1.6, and the refractive index n2 of the second material layer is greater than 2.0.

4. The display panel according to claim 2, wherein a material of the first material layer is selected from the group consisting of magnesium fluoride, calcium fluoride, and silicon oxide, and a material of the second material layer is selected from the group consisting of zinc tin oxide, zinc sulfide, and zirconium oxide.

5. The display panel according to claim 2, wherein the quantum dot light conversion film is doped with quantum dots capable of emitting red, green, or yellow light.

6. The display panel according to claim 1, wherein the light-emitting device layer is a blue light-emitting device layer.

7. The display panel according to claim 1, wherein when a wavelength of incident light ranges from 490 to 670 nm, and a reflectance of the optical adjustment film is higher than 90%.

8. The display panel according to claim 1, wherein when a wavelength of incident light is less than 490 nm, a reflectance of the optical adjustment film is lower than 10%.

9. The display panel according to claim 1, wherein the light-emitting device layer comprises a transparent electrode, an organic layer, and a reflective electrode.

10. A manufacturing method of a display panel, comprising:
sequentially forming a light-emitting device layer and a cover plate on a side of a substrate;
forming an optical adjustment film on another side of the substrate; and
forming a quantum dot light conversion film on a surface of the optical adjustment film to obtain the display panel;
wherein a method for forming the optical adjustment film is one of vacuum evaporation, magnetron sputtering, chemical deposition, or atomic layer deposition.

11. The manufacturing method of the display panel according to claim 10, wherein a method for forming the light-emitting device layer is vacuum evaporation, and a method for forming the quantum dot light conversion film is coating or bonding after separate preparation.

12. The manufacturing method of the display panel according to claim 10, wherein the display panel comprises:
the substrate, the light-emitting device layer, and a the cover plate stacked sequentially;
the quantum dot light conversion film disposed on a side of the substrate away from the light-emitting device layer; and
the optical adjustment film disposed between the substrate and the quantum dot light conversion film.

13. The manufacturing method of the display panel according to claim 12, wherein the optical adjustment film is formed by alternately stacking a plurality of refractive units, and each of the plurality of refractive units comprises a first material layer having a refractive index n1 and a second material layer having a refractive index n2.

14. The manufacturing method of the display panel according to claim 13, wherein the refractive index n1 of the first material layer is less than 1.6, and the refractive index n2 of the second material layer is greater than 2.0.

15. The manufacturing method of the display panel according to claim 13, wherein a material of the first material layer is selected from the group consisting of magnesium fluoride, calcium fluoride, and silicon oxide, and a material of the second material layer is selected from the group consisting of zinc tin oxide, zinc sulfide, and zirconium oxide.

16. The manufacturing method of the display panel according to claim 10, wherein the quantum dot light conversion film is doped with quantum dots capable of emitting red, green, or yellow light.

17. The manufacturing method of the display panel according to claim 10, wherein the light-emitting device layer is a blue light-emitting device layer.

18. The manufacturing method of the display panel according to claim 10, wherein a wavelength of incident light ranges from 490 to 670 nm, and a reflectance of the optical adjustment film is higher than 90%.

19. The manufacturing method of the display panel according to claim 10, wherein when a wavelength of incident light is less than 490 nm, a reflectance of the optical adjustment film is lower than 10%.

20. The manufacturing method of the display panel according to claim 10, wherein the light-emitting device layer comprises a transparent electrode, an organic layer, and a reflective electrode.
